(19) United States
(12) Patent Application Publication
(10) Pub. No.: US 2017/0040289 A1
(43) Pub. Date: Feb. 9, 2017

(54) SEMICONDUCTOR PACKAGE

(71) Applicant: Samsung Electronics Co., Ltd., Suwon-si (KR)

(72) Inventors: Jae-Gil LIM, Asan-si (KR); JUNYOUNG KO, Cheonan-si (KR); SEYEOUL PARK, Cheonan-si (KR); Kyung-A JIN, Asan-si (KR)

(21) Appl. No.: 15/213,392

(22) Filed: Jul. 18, 2016

(30) Foreign Application Priority Data
Aug. 3, 2015 (KR) 10-2015-0109533

(51) Int. Cl. H01L 25/065; H01L 25/18

(52) U.S. Cl. CPC H01L 25/0652; H01L 25/18; H01L 2225/06506; H01L 2225/06562; H01L 2225/06582

(57) ABSTRACT

Embodiments of a semiconductor package includes first semiconductor chips stacked on a substrate to form an offset stack structure, and a second semiconductor chip disposed on the substrate and electrically connected to the substrate through an input/output (I/O) wire and a ground wire. The first semiconductor chips are stacked to slope toward the second semiconductor chip. A height of the topmost portion of the ground wire from the top of the second semiconductor chip is higher than a height of the topmost portion of the I/O wire from the top of second semiconductor chip.

### CROSS-REFERENCE TO RELATED APPLICATION

This U.S. non-provisional patent application claims priority under 35 U.S.C. §119 to Korean Patent Application No. 10-2015-0109533, filed on Aug. 3, 2015, in the Korean Intellectual Property Office, the disclosure of which is hereby incorporated by reference in its entirety.

### BACKGROUND

The inventive concepts relate to a semiconductor package and, more particularly, to a semiconductor package including a ground wire.

A general stack package may have a structure that includes a plurality of stacked semiconductor chips. For example, the stack package may include semiconductor chips sequentially stacked on a printed circuit board (PCB). Connecting pads may be formed on the semiconductor chips. The connecting pads may be connected to each other through bonding wires, and thus the semiconductor chips may be electrically connected to each other. A logic chip controlling the semiconductor chips may be mounted on the printed circuit board (PCB). To reduce an area of the stack package, the semiconductor chips may be stacked to form a stepped structure and the logic chip may be disposed on the printed circuit board (PCB) at a side of the stacked semiconductor chips. Thus, the logic chip and the stacked semiconductor chips may be disposed side by side on the printed circuit board (PCB).

### SUMMARY

Embodiments of the inventive concepts may provide a semiconductor package that includes a ground wire capable of preventing static electricity from being generated in a semiconductor chip.

In one aspect, a semiconductor package may include a plurality of first semiconductor chips stacked on a substrate in an offset stack structure, and a second semiconductor chip disposed on the substrate and electrically connected to the substrate through an input/output (I/O) wire and a ground wire. The plurality of first semiconductor chips may be stacked to slope toward the second semiconductor chip, and a height of a topmost portion of the ground wire from a top surface of the second semiconductor chip may be higher than a height of a topmost portion of the I/O wire from the top surface of the second semiconductor chip.

In an embodiment, the ground wire may connect the top surface of the second semiconductor chip to a ground pattern of the substrate and may have a plurality of protrusions protruding toward the plurality of first semiconductor chips.

In an embodiment, the height of the topmost portion of the ground wire from the top surface of the second semiconductor chip may be higher than the height of the topmost portion of the I/O wire from the top surface of the second semiconductor chip by about 50 μm or more.

In an embodiment, the ground wire may include a first ground wire connecting a top surface of the second semiconductor chip to the substrate exposed between the second semiconductor chip and the plurality of first semiconductor chips, and a second ground wire provided to be opposite to the first ground wire.

In an embodiment, the first ground wire may be vertically overlapped with one or more of the plurality of first semiconductor chips.

In an embodiment, the substrate may include a first ground pattern connected to the first ground wire, and a second ground pattern connected to the second ground wire.

In an embodiment, the plurality of first semiconductor chips may be memory chips, and the second semiconductor chip may be a logic chip.

In an embodiment, the semiconductor package may further include a molding layer covering the plurality of first semiconductor chips and the second semiconductor chip.

In another aspect, a semiconductor package may include a plurality of first semiconductor chips stacked on a substrate in an offset stack structure, and a ground wire provided on the substrate in which the ground wire has a first end and a second end. The first end and the second end of the ground wire may be respectively connected to ground patterns provided on the substrate, and the ground wire may be provided between the substrate and exposed bottom surfaces of one or more of the plurality of first semiconductor chips.

In an embodiment, the ground wire may have at least one protrusion protruding toward the plurality of first semiconductor chips.

In an embodiment, the semiconductor package may further include a second semiconductor chip spaced apart from the plurality of first semiconductor chips and disposed on the substrate. The ground wire may be provided on the substrate between the second semiconductor chip and the plurality of first semiconductor chips.

In an embodiment, the second semiconductor chip may be electrically connected to the substrate through an input/output (I/O) wire, and a height of a topmost portion of the ground wire from a top surface of the second semiconductor chip may be higher than a height of a topmost portion of the I/O wire from the top surface of the second semiconductor chip.

In an embodiment, the semiconductor package may further include a second ground wire opposite to the ground wire with respect to the second semiconductor chip.

In an embodiment, levels of the topmost portions of the ground wire and a topmost portion of the second ground wire may be higher than a level of a topmost portion of the I/O wire by about 50 μm or more.

In an embodiment, the plurality of first semiconductor chips may be stacked to have a stepped structure having an upward slope toward the second semiconductor chip.

In another aspect, a semiconductor package comprises a substrate, a first semiconductor chip, a plurality of second semiconductor chips, at least one input/output (I/O) wires, and at least one first ground wire. The first semiconductor chip may be disposed on the substrate, and the first semiconductor chip may have a top surface. The plurality of second semiconductor chips may be stacked on the substrate in an offset stack structure having a slope toward the first semiconductor chip. The at least one I/O wire may electrically connect the first semiconductor chip to the substrate. The at least one first ground wire may electrically connected to the substrate between the first semiconductor chip and the plurality of second semiconductor chips. A height of a topmost portion of the at least one first ground wire from the top surface of the first semiconductor chip may be higher than a height of a topmost portion of the at least one I/O wire from the top surface of the first semiconductor chip.

In an embodiment, the height of the topmost portion of the at least one first ground wire from the top surface of the first semiconductor chip may be higher than the height of the topmost portion of the I/O wire from the top surface of the first semiconductor chip by about 50 μm or more.

In an embodiment, the at least one first ground wire may comprise at least one protrusion protruding toward the plurality of second semiconductor chips.

In an embodiment, the at least one first ground wire may comprise a first end and a second end in which the first end and the second end of the at least one first ground wire may each be separately connected to the substrate. In an embodiment, the at least one first ground wire may comprise at least one protrusion protruding toward the plurality of second semiconductor chips.

In an embodiment, the at least one I/O wire and the at least one first ground wire may be alternatively arranged with respect to each other.

In an embodiment, the at least one first ground wire may comprise a first end and a second end in which the first end of the at least one first ground wire may be connected to the first semiconductor chip on a first side of the first semiconductor chip, and the second end of the at least one first ground wire may be connected to the substrate between the first semiconductor chip and the plurality of second semiconductor chips. The semiconductor package may further comprise at least one second ground wire comprising a first end and a second end in which the first end of the at least one second ground wire may be connected to the first semiconductor chip of a second side of the first semiconductor chip, and the second end of the at least one second ground wire may be connected to the substrate on a side of the first semiconductor chip that is opposite the first side of the first semiconductor chip.

### BRIEF DESCRIPTION OF THE DRAWINGS

The inventive concepts will become more apparent in view of the attached drawings and accompanying detailed description.

FIG. 1 is a plan view illustrating a semiconductor package according to embodiment of the inventive concepts.

FIGS. 2 and 3 are cross-sectional views taken along a line A-A′ of FIG. 1 to illustrate semiconductor packages according to embodiments of the inventive concepts.

FIG. 4 is a plan view illustrating a semiconductor package according to embodiments of the inventive concepts.

FIG. 5 is a cross-sectional view taken along a line B-B′ of FIG. 4.

FIG. 6 is a plan view illustrating a semiconductor package according to embodiment of the inventive concepts.

FIGS. 7 and 8 are cross-sectional views taken along a line C-C′ of FIG. 6 to illustrate semiconductor packages according to embodiments of the inventive concepts.

FIG. 9 is a plan view illustrating a semiconductor package according to embodiments of the inventive concepts.

FIG. 10 is a cross-sectional view taken along a line D-D′ of FIG. 9.

### DETAILED DESCRIPTION OF THE EMBODIMENTS

The inventive concepts will now be described more fully hereinafter with reference to the accompanying drawings in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity. The same reference numerals or the same reference designators denote the same elements throughout the specification.

In addition, exemplary embodiments are described herein with reference to cross-sectional views and/or plan views that are idealized exemplary views. In the drawings, the thicknesses of layers and regions are exaggerated for clarity. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

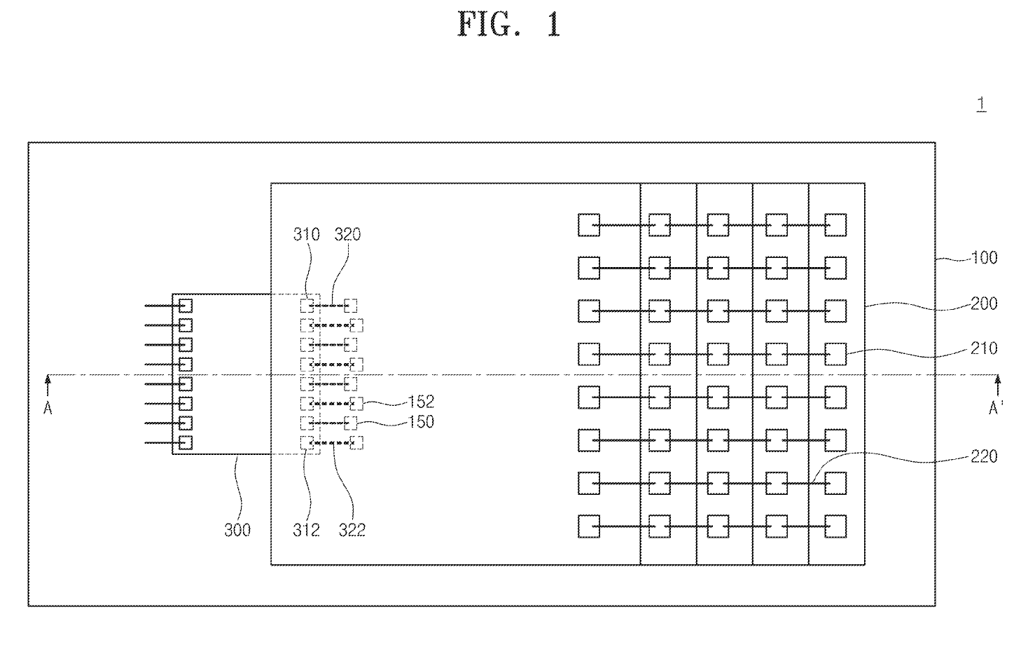

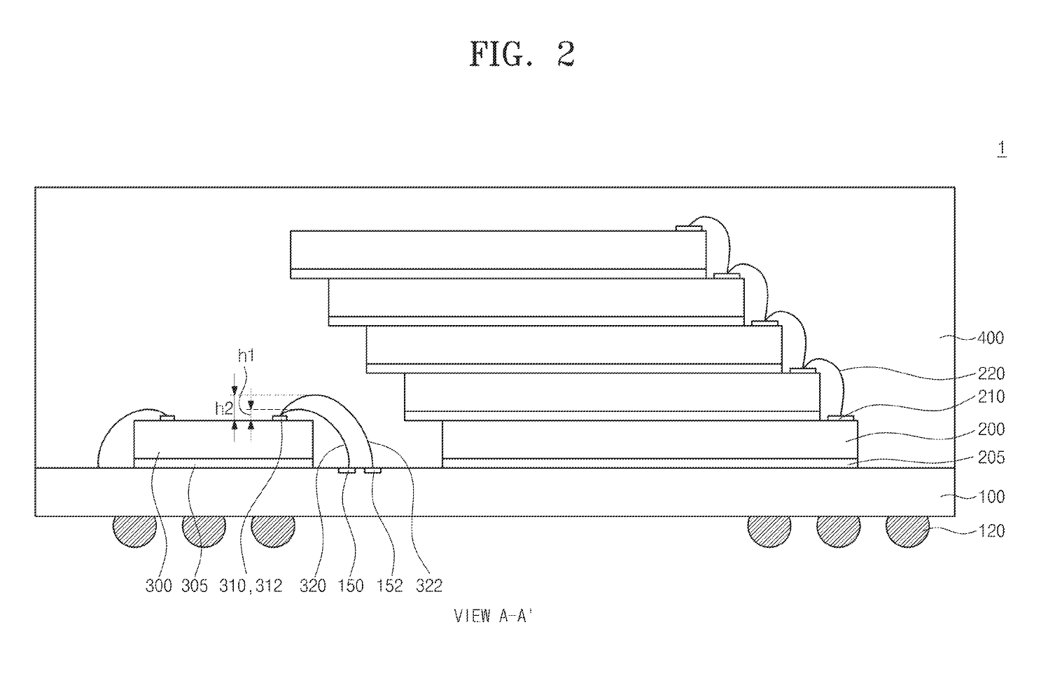

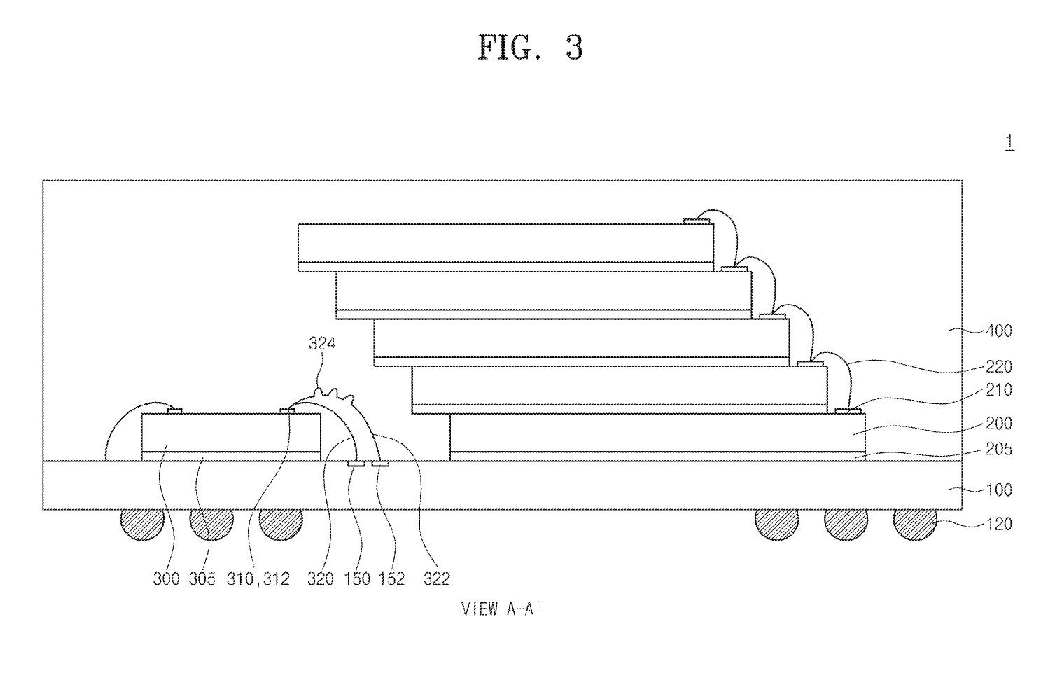

FIG. 1 is a plan view illustrating a semiconductor package according to embodiment of the inventive concepts. FIGS. 2 and 3 are cross-sectional views taken along a line A-A′ of FIG. 1 to illustrate semiconductor packages according to embodiments of the inventive concepts.

Referring to FIGS. 1 and 2, a semiconductor package 1 may include a substrate 100, a plurality of first semiconductor chips 200, and a second semiconductor chip 300. At least one external terminal 120 may be provided on a bottom surface of the substrate 100. The external terminal 120 may include at least one of tin (Sn), lead (Pb), nickel (Ni), gold (Au), silver (Ag), copper (Cu), or bismuth (Bi). The external terminal 120 may include a solder ball or a solder pad, and the semiconductor package 1 may have a ball grid array (BGA) structure, a fine ball-grid array (FBGA) structure, or a land grid array (LGA) structure depending on the type of the external terminal 120.

The substrate 100 may be a printed circuit board (PCB) having at least one signal pattern 150 and at least one ground pattern 152 that are disposed on a top surface of the PCB. The substrate 100 may have a structure in which insulating layers and interconnection layers are alternately stacked. The ground pattern 152 may be grounded.

The plurality of first semiconductor chips 200 may be provided on the substrate 100. The first semiconductor chips 200 may be, for example, memory chips. The first semiconductor chips 200 may be stacked to form an offset stack structure. The first semiconductor chip 200 may be connected to each other through connecting wires 220. An adhesive layer 205 may be provided between the first semiconductor chips 200 that are vertically adjacent to each other. In addition, an adhesive layer 205 may also be provided between the substrate 100 and the lowermost one of the first semiconductor chips 200. The second semiconductor chip 300 may be disposed on the substrate 100 at a side of the first semiconductor chips 200. The first semiconductor chips 200 may be stacked to slope toward the second semiconductor chip 300. In other words, the first semiconductor chips 200 may be stacked to have a stepped structure including an upward slope toward the second semiconductor chip 300. Since the first semiconductor chips 200 are stacked to form the stepped structure, portions of top surfaces of the first semiconductor chips 200 may be exposed, and active surfaces may be provided to the exposed top surfaces of the first semiconductor chips 200. Connecting pads 210 that are in contact with the connecting wires 220 may be provided on the exposed top surfaces of the first semiconductor chips 200. The connecting pads 210 may include at least one of tin (Sn), lead (Pb), nickel (Ni), gold (Au), silver (Ag), copper (Cu), or bismuth (Bi).

As described above, the second semiconductor chip 300 may be provided on the substrate 100 at a side of the plurality of first semiconductor chips 200. For example, the second semiconductor chip 300 may be a logic chip (e.g., a controller) controlling the first semiconductor chips 200. An adhesive layer 305 may be provided between the second semiconductor chip 300 and the substrate 100. A size of the second semiconductor chip 300 may be smaller than the sizes of the first semiconductor chips 200. A portion of the second semiconductor chip 300 may be vertically overlapped by one or more of the first semiconductor chips 200. A top surface of the second semiconductor chip 300 may be an active surface. At least one input/output (I/O) pad 310 and at least one ground pad 312 may be provided on the top surface of the second semiconductor chip 300.

The second semiconductor chip 300 may be electrically connected to the substrate 100 through at least one input/output (I/O) wire 320 and at least one ground wire 322, which are formed by a wire bonding technique. The I/O wires 320 and the ground wires 322 may be alternately arranged when viewed from a plan view. The I/O wire 320 may electrically connect the signal pattern 150 of the substrate 100 to the I/O pad 310 provided on the top surface of the second semiconductor chip 300. The ground wire 322 may electrically connect the ground pad 312 provided on the top surface of the second semiconductor chip 300 to the ground pattern 152 of the substrate 100 that is exposed between the second semiconductor chip 300 and the first semiconductor chips 200. The ground wire 322 may be vertically overlapped by one or more of the first semiconductor chips 200. The ground wire 322 may be formed of a metal material having a very high electrical conductivity. For example, the I/O wire 320 and the ground wire 322 may be formed of copper (Cu) or gold (Au). Each of the I/O and ground wires 320 and the 322 may have a loop shape. The I/O wire 320 may have a wire-loop shape in which the topmost portion of the I/O wire 320 has a first height h1 from the top surface of the second semiconductor chip 300, and the ground wire 322 may have a wire-loop shape in which the topmost portion of the ground wire 322 has a second height h2 from the top surface of the second semiconductor chip 300. For example, the second height h2 may be higher than the first height h1 by about 50 μm or more. In other words, a difference between the second height h2 and the first height h1 may be about 50 μm or more. The ground wire 322 may protrude further toward the first semiconductor chips 200 than the I/O wire 320. In other words, the ground wire 322 may be closer to the first semiconductor chips 200 than the I/O wire 320.

A molding layer 400 may be provided to cover the top surface of the substrate 100, the first semiconductor chips 200, and the second semiconductor chip 300. The molding layer 400 may include an insulating polymer material, such as an epoxy molding compound (EMC).

Generally, the first semiconductor chips 200 may become charged with charges provided externally to the semiconductor package 1, and thus charges may exist on surfaces of the first semiconductor chips 200. Such charges of the surfaces of the first semiconductor chips 200 may be transmitted to the second semiconductor chip 300. The charges may generate static electricity at the active surface of the second semiconductor chip 300, thereby causing a failure of the second semiconductor chip 300. However, according to embodiments of the inventive concepts, since the ground wire 322 is closer to the first semiconductor chips 200 than the I/O wire 320 is, any charges existing on the surfaces of the first semiconductor chips 200 may be transmitted to the ground wire 322, not to the second semiconductor chip 300. The charges transmitted to the ground wire 322 may be transmitted to the ground pattern 152, and the ground pattern 152 may discharge the charges externally to the semiconductor package 1. Thus, the ground wire 322 may prevent the static electricity from being generated in the second semiconductor chip 300. In other words, it is possible to prevent a failure of the second semiconductor chip 300 that may be caused by static electricity.

Additionally, in a general technique, I/O wires 320 may be connected to each other to prevent an occurrence of static electricity in a situation in which multiple semiconductor packages that have not been separated, or cut, from each other and, therefore, form a strip structure. In a situation in which the I/O wires 320 are connected to each other, an electrical inspection of each of the I/O wires 320 may not be performed until the connections between the I/O wires 320 are be removed when the semiconductor packages are separated from each other. However, according to embodiments of the inventive concepts, the ground wire 322 may be additionally provided to prevent the static electricity from being generated in the second semiconductor chip 300. Thus, it is not required to connect the I/O wires 320 to each other in a strip structure. This means that the electrical inspection of the I/O wires 320 of the semiconductor packages 1 if multiple semiconductor packages 1 are arranged in a strip structure may be easily performed.

Referring to FIGS. 1 and 3, a ground wire 322 may be provided to connect the second semiconductor chip 300 to the substrate 100. The ground wire 322 may connect the ground pad 312 disposed on the second semiconductor chip 300 to the ground pattern 152 disposed on the substrate 100. The ground wire 322 may have a wire-loop shape that is higher than the I/O wire 320 and may have one or more protrusions 324 protruding toward the first semiconductor chips 200. Distances between the ground wire 322 and the first semiconductor chips 200 may be reduced due to the protrusions 324. In addition, the protrusions 324 may increase a surface area of the ground wire 322 to thereby increase the amount of charges reaching the ground wire 322 from the surfaces of the first semiconductor chips 200 that may be charged. Thus, the charges existing on the surfaces of the first semiconductor chips 200 that are charged may be transmitted to the ground pad 152 through the ground wire 322 and may then be discharged externally to the semiconductor package 1.

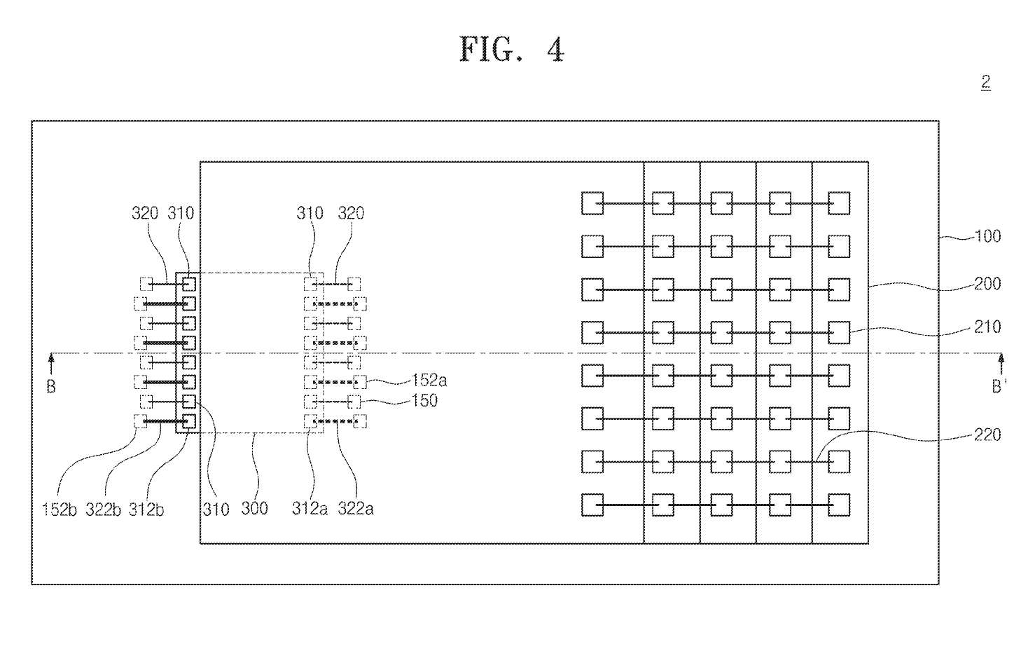

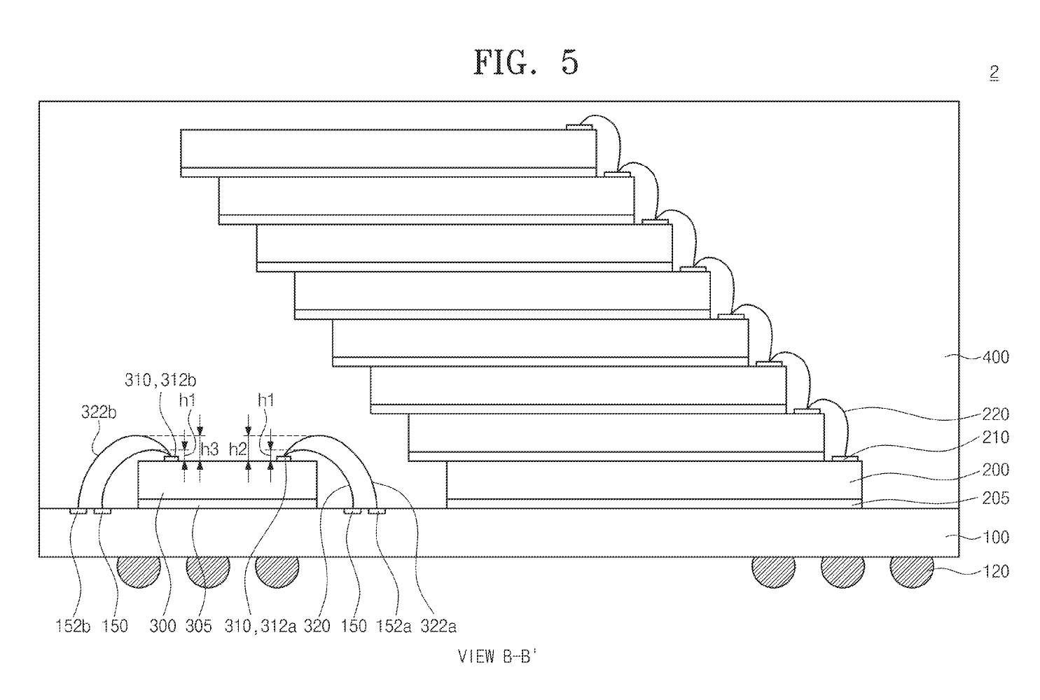

FIG. 4 is a plan view illustrating a semiconductor package 2 according to embodiments of the inventive concepts. FIG. 5 is a cross-sectional view taken along a line B-B′ of FIG. 4. In the present embodiment, the descriptions about the elements that are the same as in the above embodiments will be omitted or mentioned briefly for the purpose of ease and convenience in explanation.

Referring to FIGS. 4 and 5, a plurality of first semiconductor chips 200 may be stacked on a substrate 100, and some of the first semiconductor chips 200 may vertically overlap a second semiconductor chip 300 that is disposed on the substrate 100. Charges existing on surfaces of the first semiconductor chips 200 may affect an entire region of the second semiconductor chip 300. Charges existing on the lower first semiconductor chips 200 may affect a first edge portion of the second semiconductor chip 300 that is adjacent to the first semiconductor chips 200, and charges existing on the upper first semiconductor chips 200 may affect another edge portion, which is opposite to the first edge portion of the second semiconductor chip 300.

A semiconductor package 2 may include a first ground wire 322a and a second ground wire 322b that connect the second semiconductor chip 300 to the substrate 100. The first ground wire 322a may connect a first ground pad 312a provided on one edge portion of the second semiconductor chip 300 to a first ground pattern 152a provided on the substrate 100, and the second ground wire 322b may connect a second ground pad 312b provided on another edge portion of the second semiconductor chip 300 to a second ground pattern 152b provided on the substrate 100. The first ground pattern 152a may be provided on the substrate 100 exposed between the second semiconductor chip 300 and the first semiconductor chips 200, and the second ground pattern 152b may be provided on an opposite side of the second semiconductor chip 300 from the first ground pattern 152b with respect to the second semiconductor chip 300.

The first ground wire 322a and the second ground wire 322b may have wire-loop shapes that extend higher than the I/O wire 320. For example, the I/O wire 320 may have a wire-loop shape in which the topmost portion of the I/O wire 320 has a first height h1 from the top surface of the second semiconductor chip 300, the first ground wire 322a may have a wire-loop shape in which the topmost portion of the first ground wire 322a has a second height h2 from the top surface of the second semiconductor chip 300, and the second ground wire 322b may have a wire-loop shape in which the topmost portion of the second ground wire 322b has a third height h3 from the top surface of the second semiconductor chip 300. In an embodiment, each of the second and third heights h2 and h3 may be higher than the first height h1 by about 50 μm or more. In other words, a difference between each of the second and third heights h2 and h3 and the first height h1 may be equal to or greater than about 50 μm. The first and second ground wires 322a and 322b may protrude further toward the first semiconductor chips 200 than the adjacent I/O wires 320. In other words, since the first and second ground wires 322a and 322b are closer to the first semiconductor chips 200 than the adjacent I/O wires 320, the charges of the first semiconductor chips 200 that may exist may be transmitted to the first and second ground wires 322a and 322b, not to the I/O wires 320. The charges transmitted to the first and second ground wires 322a and 322b may be discharged externally to the semiconductor package 2 through the first and second ground patterns 152a and 152b.

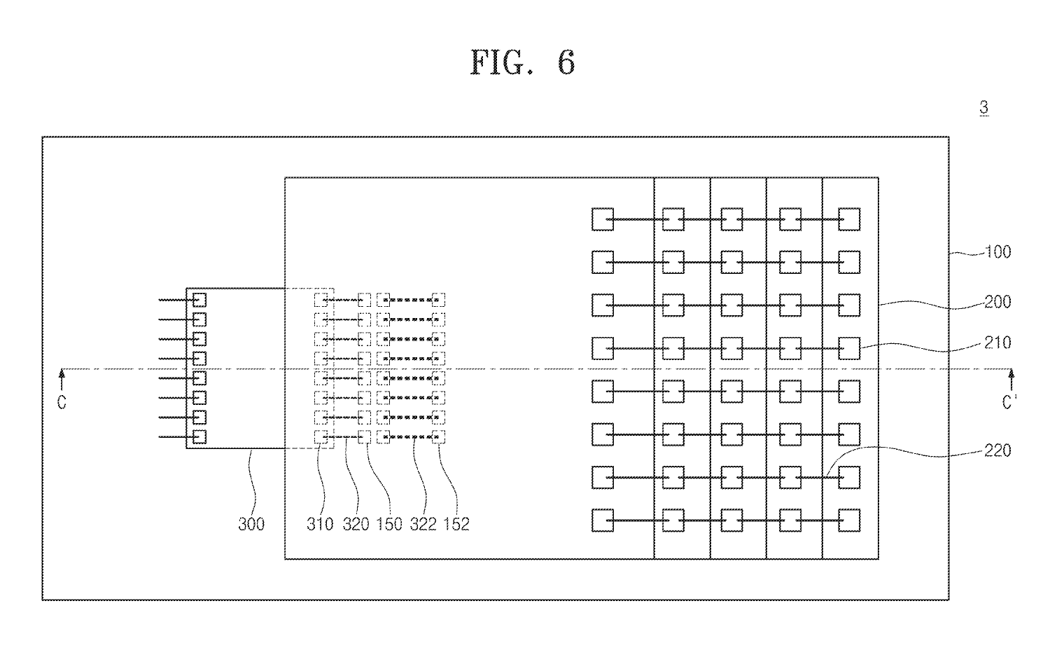

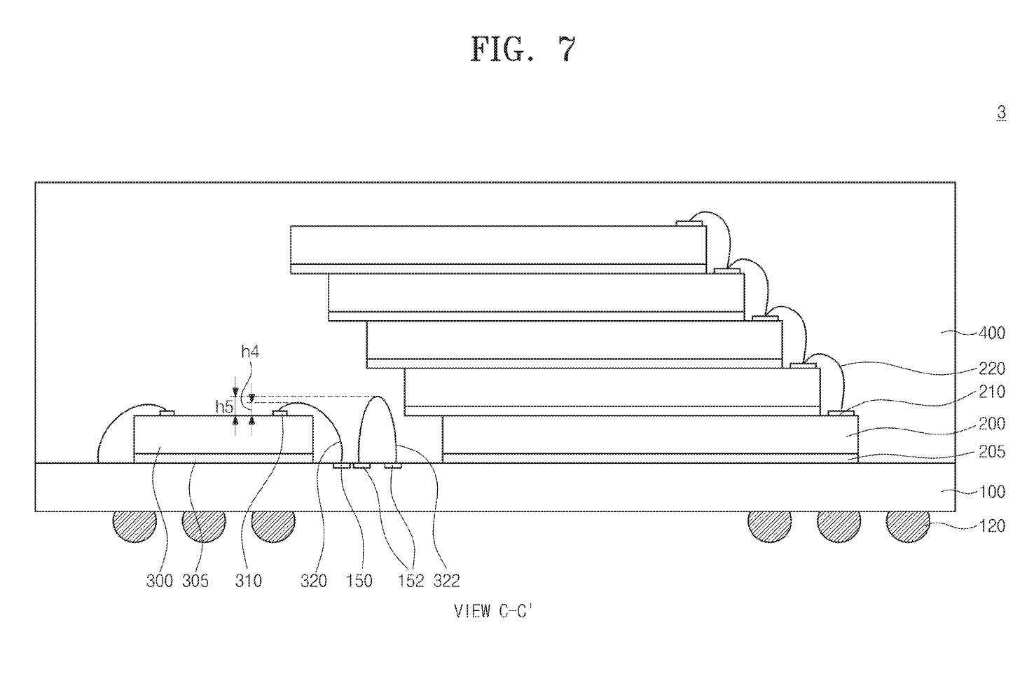

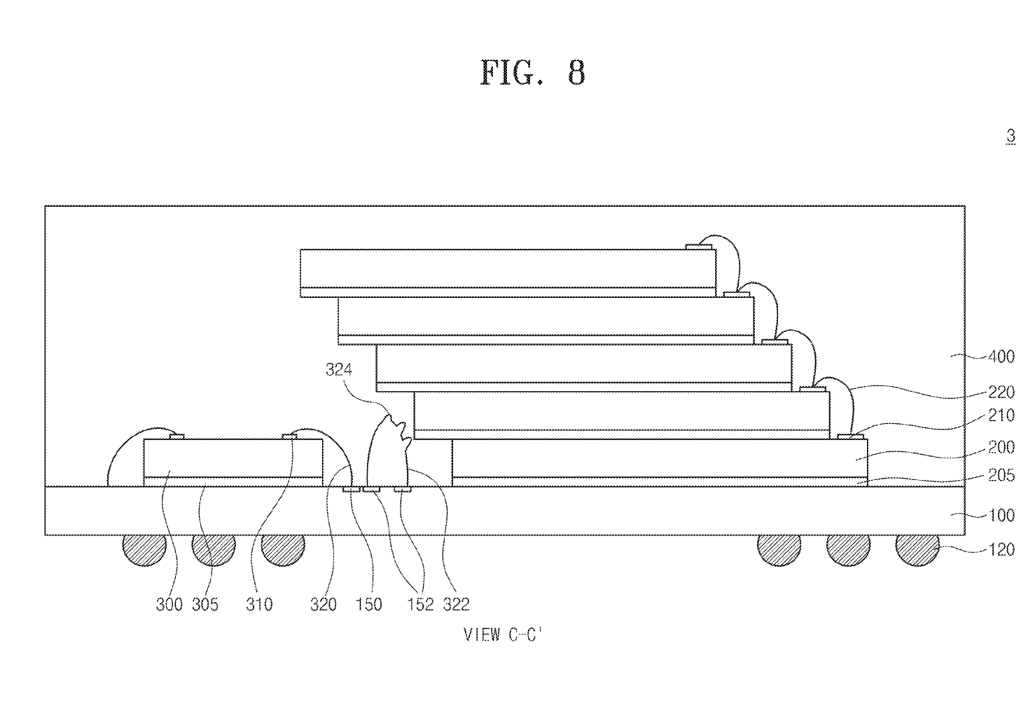

FIG. 6 is a plan view illustrating a semiconductor package according to embodiment of the inventive concepts. FIGS. 7 and 8 are cross-sectional views taken along a line C-C′ of FIG. 6 to illustrate semiconductor packages according to embodiments of the inventive concepts. In the present embodiment, the descriptions about the elements that are the same as in the above embodiments will be omitted or mentioned briefly for the purpose of ease and convenience in explanation.

Referring to FIGS. 6 and 7, a semiconductor package 3 may include a substrate 100, first semiconductor chips 200, and a second semiconductor chip 300.

The second semiconductor chip 300 may be electrically connected to the substrate 100 through at least one I/O wire 320 that is formed by a wire bonding technique. The I/O wires 320 may electrically connect I/O pads 310 provided on the top surface of the second semiconductor chip 300 to signal patterns 150 provided on the substrate 100. For example, the I/O wire 320 may include copper (Cu) or gold (Au). The I/O wire 320 may have a loop shape. The I/O wire 320 may have a wire-loop shape in which the topmost portion of the I/O wire 320 has a fourth height h4 from the top surface of the second semiconductor chip 300.

A ground wire 322 may be provided on the substrate 100 that is exposed between the second semiconductor chip 300 and the first semiconductor chips 200. The ground wire 322 may be disposed between the substrate 100 and the bottom surfaces of some of the first semiconductor chips 200 that are exposed toward the substrate 100. In other words, the ground wire 322 may be vertically overlapped by some of the first semiconductor chips 200 and may be disposed adjacent to the second semiconductor chip 300.

The ground wire 322 may protrude from the substrate 100 toward the first semiconductor chips 200, and both ends of the ground wire 322 may be connected to ground patterns 152 disposed on the substrate 100. The ground wire 322 may have a wire-loop shape in which the topmost portion has a fifth height h5 from the top surface of the second semiconductor chip 300. The ground wire 322 may be formed of a metal material having a very high electrical conductivity. For example, the ground wire 322 may be formed of copper (Cu) or gold (Au). The ground wire 322 may have a loop shape. The ground wire 322 may protrude further toward the first semiconductor chips 200 than the I/O wires 320. For example, the fifth height h5 of the ground wire 322 may be higher than the fourth height h4 of the I/O wire 320 by about 50 μm or more.

The first semiconductor chips 200 may become charged provided externally from the semiconductor package 3, and such charges existing on surfaces of the first semiconductor chips 200 may generate static electricity at the active surface of the second semiconductor chip 300, thereby causing a failure of the second semiconductor chip 300. According to embodiments of the inventive concepts, the ground wire 322 may be disposed between the I/O wire 320 and the first semiconductor chips 200 and thus, any charges existing on the surfaces of the first semiconductor chips 200 may be transmitted to the ground wire 322, not to the second semiconductor chip 300. The charges transmitted to the ground wire 322 may be discharged externally to the semiconductor package 3 through the ground patterns 152.

Referring to FIGS. 6 and 8, a ground wire 322 may be provided on the substrate 100 exposed between the second semiconductor chip 300 and the first semiconductor chips 200. The ground wire 322 may have a loop shape that is convex from the substrate 100 toward the first semiconductor chips 200. The ground wire 322 may have the loop shape that extends higher than the I/O wire 320 and may have one or more protrusions 324 protruding toward the first semiconductor chips 200. Distances between the ground wire 322 and the first semiconductor chips 200 may be reduced due to the protrusions 324. In addition, the protrusions 324 may increase a surface area of the ground wire 322 to thereby increase the amount of charges reaching the ground wire 322 from the surfaces of the first semiconductor chips 200. Thus, the charges existing on the surfaces of the first semiconductor chips 200 that may be charged may be transmitted to the ground pad 152 through the ground wire 322 and may then be discharged externally to the semiconductor package 3.

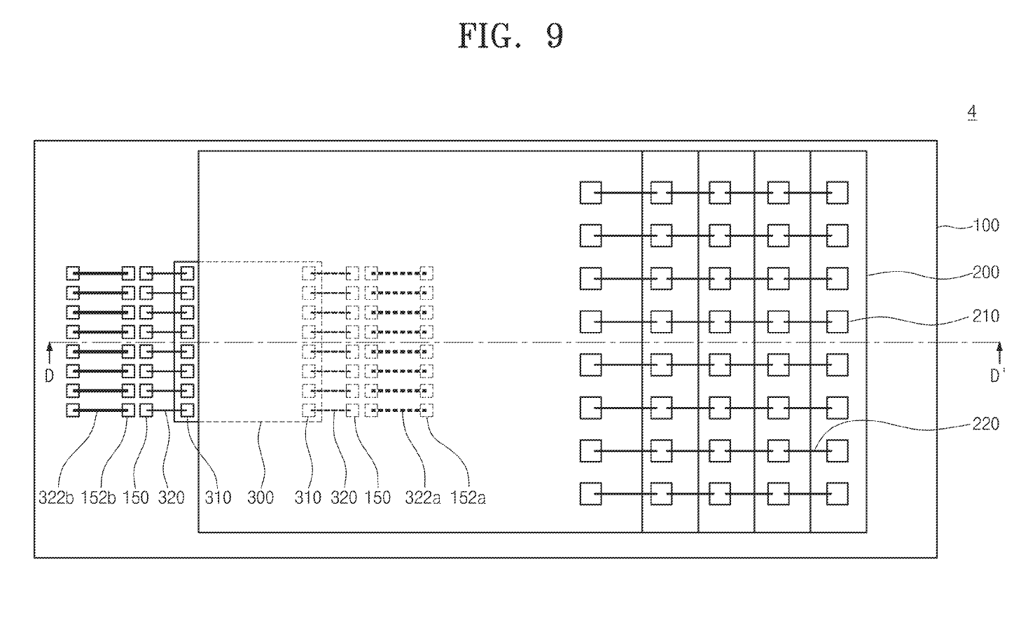

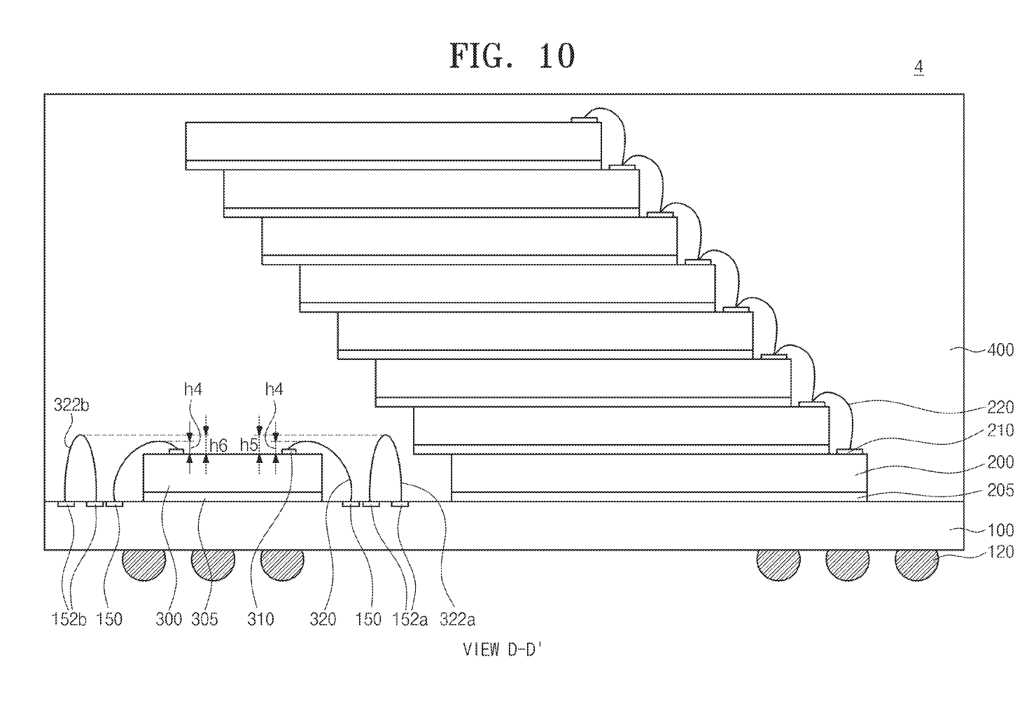

FIG. 9 is a plan view illustrating a semiconductor package according to embodiments of the inventive concepts. FIG. 10 is a cross-sectional view taken along a line D-D′ of FIG. 9. In the present embodiment, the descriptions about the elements that are the same as in the above embodiments will be omitted or mentioned briefly for the purpose of ease and convenience in explanation.

Referring to FIGS. 9 and 10, a plurality of first semiconductor chips 200 may be stacked on a substrate 100, and some of the first semiconductor chips 200 may vertically overlap a second semiconductor chip 300. Charges existing on surfaces of the first semiconductor chips 200 may affect an entire region of the second semiconductor chip 300. Charges existing on the lower first semiconductor chips 200 may affect a first edge portion of the second semiconductor chip 300 that is adjacent to the first semiconductor chips 200, and charges existing the upper first semiconductor chips 200 may affect another edge portion that is opposite to the first edge portion of the second semiconductor chip 300.

A semiconductor package 4 may include a first ground wire 322a provided on the substrate 100 exposed between the second semiconductor chip 300 and the first semiconductor chips 200, and a second ground wire 322b may be provided on an opposite side of the second semiconductor chip 300 from the first ground wire 322a. Both ends of the first ground wire 322a may be connected to first ground patterns 152a disposed on the substrate 100 exposed between the second semiconductor chip 300 and the first semiconductor chips 200. Both ends of the second ground wire 322b may be connected to second ground patterns 152b. The first ground wire 322a and the second ground wire 322b may have wire-loop shapes that extend higher than the I/O wire 320. For example, the I/O wire 320 may have a wire-loop shape in which the topmost portion of the I/O wire 320 has a fourth height h4 from the top surface of the second semiconductor chip 300, the first ground wire 322a may have a wire-loop shape in which the topmost portion of the first ground wire 322a has a fifth height h5 from the top surface of the second semiconductor chip 300, and the second ground wire 322b may have a wire-loop shape in which the topmost portion of the second ground wire 322b has a sixth height h6 from the top surface of the second semiconductor chip 300. In an embodiment, each of the fifth and sixth heights h5 and h6 may be higher than the fourth height h4 by about 50 μm or more. In other words, a difference between each of the fifth and sixth heights h5 and h6, and the fourth height h4 may be equal to or greater than about 50 μm. The first and second ground wires 322a and 322b may protrude further from the substrate 100 toward the first semiconductor chips 200 than the adjacent I/O wires 320. In other words, since the first and second ground wires 322a and 322b are closer to the first semiconductor chips 200 than the adjacent I/O wires 320, the charges of the first semiconductor chips 200 may be transmitted to the first and second ground wires 322a and 322b. The charges transmitted to the first and second ground wires 322a and 322b may be discharged externally to the semiconductor package 4 through the first and second ground patterns 152a and 152b.

According to embodiments of the inventive concepts, the ground wire may be closer to the first semiconductor chips than the I/O wire, and thus, it is possible to prevent the charges existing on the surfaces of the first semiconductor chips from being transmitted to the I/O wire and thereby generate the static electricity.

According to embodiments of the inventive concepts, the ground wire may be provided between the second semiconductor chip and the first semiconductor chips, thereby preventing the charges existing on the surfaces of the first semiconductor chips from being transmitted to the second semiconductor chip and generate static electricity.

According to embodiments of the inventive concepts, the static electricity of the second semiconductor chip may be prevented if the I/O wires are not connected to each other before multiple semiconductor packages are separated from each other, that is, while multiple semiconductor packages for a strip structure, thereby enabling electrical inspection of the multiple semiconductor packages in the strip structure.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A semiconductor package, comprising:
a plurality of first semiconductor chips stacked on a substrate in an offset stack structure; and
a second semiconductor chip disposed on the substrate and electrically connected to the substrate through an input/output (I/O) wire and a ground wire,
wherein the plurality of first semiconductor chips are stacked to slope toward the second semiconductor chip, and
wherein a height of a topmost portion of the ground wire from a top surface of the second semiconductor chip is higher than a height of a topmost portion of the I/O wire from the top surface of the second semiconductor chip.

2. The semiconductor package of claim 1, wherein the ground wire connects the top surface of the second semiconductor chip to a ground pattern of the substrate, and
wherein the ground wire has a plurality of protrusions protruding toward the plurality of first semiconductor chips.

3. The semiconductor package of claim 1, wherein the height of the topmost portion of the ground wire from the top surface of the second semiconductor chip is higher than the height of the topmost portion of the I/O wire from the top surface of the second semiconductor chip by about 50 μm or more.

4. The semiconductor package of claim 1, wherein the ground wire comprises:
a first ground wire connecting the top surface of the second semiconductor chip to the substrate exposed between a first side of the second semiconductor chip and the plurality of first semiconductor chips; and
a second ground wire provided to be opposite to the first ground wire.

5. The semiconductor package of claim 4, wherein the first ground wire is vertically overlapped by one or more of the plurality of first semiconductor chips.

6. The semiconductor package of claim 4, wherein the substrate comprises:
a first ground pattern connected to the first ground wire; and
a second ground pattern connected to the second ground wire.

7. The semiconductor package of claim 1, wherein the plurality of first semiconductor chips are memory chips, and
wherein the second semiconductor chip is a logic chip.

8. The semiconductor package of claim 1, further comprising:
a molding layer covering the plurality of first semiconductor chips and the second semiconductor chip.

9. A semiconductor package, comprising:
a plurality of first semiconductor chips stacked on a substrate in an offset stack structure; and
a ground wire provided on the substrate, the ground wire having a first end and a second end,
wherein the first end and the second end of the ground wire are respectively connected to ground patterns provided on the substrate, and
wherein the ground wire is provided between the substrate and exposed bottom surfaces of one or more of the plurality of first semiconductor chips.

10. The semiconductor package of claim 9, wherein the ground wire has at least one protrusion protruding toward the plurality of first semiconductor chips.

11. The semiconductor package of claim 9, further comprising:
a second semiconductor chip spaced apart from the plurality of first semiconductor chips and disposed on the substrate,
wherein the ground wire is provided on the substrate between the second semiconductor chip and the plurality of first semiconductor chips.

12. The semiconductor package of claim 11, wherein the second semiconductor chip is electrically connected to the substrate through an input/output (I/O) wire, and
wherein a height of a topmost portion of the ground wire from a top surface of the second semiconductor chip is higher than a height of a topmost portion of the I/O wire from the top surface of the second semiconductor chip.

13. The semiconductor package of claim 11, further comprising:
a second ground wire opposite to the ground wire with respect to the second semiconductor chip.

14. The semiconductor package of claim 13, wherein levels of the topmost portions of the ground wire and a top most portion of the second ground wire are higher than a level of a topmost portion of the I/O wire by about 50 μm or more.

15. The semiconductor package of claim 11, wherein the plurality of first semiconductor chips are stacked to have a stepped structure having an upward slope toward the second semiconductor chip.

16. A semiconductor package, comprising:
a substrate;
a first semiconductor chip disposed on the substrate, the first semiconductor chip having a top surface;
a plurality of second semiconductor chips stacked on the substrate in an offset stack structure having a slope toward the first semiconductor chip,
at least one input/output (I/O) wire electrically connecting the first semiconductor chip to the substrate;
at least one first ground wire electrically connected to the substrate between the first semiconductor chip and the plurality of second semiconductor chips, a height of a topmost portion of the at least one first ground wire from the top surface of the first semiconductor chip being higher than a height of a topmost portion of the at least one I/O wire from the top surface of the first semiconductor chip.

17. The semiconductor package of claim 16, wherein the height of the topmost portion of the at least one first ground wire from the top surface of the first semiconductor chip is higher than the height of the topmost portion of the I/O wire from the top surface of the first semiconductor chip by about 50 μm or more.

18. The semiconductor package of claim 17, wherein the at least one first ground wire comprises at least one protrusion protruding toward the plurality of second semiconductor chips.

19. The semiconductor package of claim 17, wherein the at least one first ground wire comprises a first end and a second end, the first end and the second end of the at least one first ground wire each being separately connected to the substrate.

20. The semiconductor package of claim 19, wherein the at least one first ground wire comprises at least one protrusion protruding toward the plurality of second semiconductor chips.
